(19) United States
(12) Patent Application Publication
(10) Pub. No.: US 2026/0068401 A1
(43) Pub. Date: Mar. 5, 2026

(54) LIGHT-EMITTING AND DRIVING DEVICE PACKAGE AND METHOD FOR MANUFACTURING THE SAME

(71) Applicant: Global Technologies Co., LTD, Hwaseong-si Gyeonggi-do (KR)

(72) Inventors: Min Seon KIM, Hwaseong-si Gyeonggi-do (KR); Seung Hyun OH, Gwangju-si Gyeonggi-do (KR); Jung Hyun PARK, Osan-si Gyeonggi-do (KR)

(73) Assignee: Global Technologies Co., LTD, Hwaseong-si Gyeonggi-do (KR)

(21) Appl. No.: 19/288,525

(22) Filed: Aug. 1, 2025

(30) Foreign Application Priority Data
Aug. 28, 2024 (KR) 10-2024-0115555

(51) Int. Cl. H10H 29/854; H01L 25/16; H10H 29/01; H10H 29/85; H10H 29/853

(52) U.S. Cl. CPC H10H 29/854; H10H 29/0362; H10H 29/853; H10H 29/857

(57) ABSTRACT

A light-emitting and driving device package and a method of manufacturing the same are disclosed. The package includes a substrate having a first pad portion and a second pad portion, a driver IC mounted on the first pad portion, a light-emitting device mounted on the second pad portion and configured to emit light upon receiving a drive signal from the driver IC, a first encapsulant formed on the substrate in a wall shape, a second encapsulant configured to cover and protect at least a portion of the driver IC, and a third encapsulant configured to cover and protect at least a portion of the light-emitting device. The disclosure enables integrated packaging of the light-emitting device and the driver IC while enhancing optical efficiency.

### CROSS-REFERENCE TO RELATED PATENT APPLICATION

The present application claims priority under 35 U.S.C. § 119(a) to Korean Patent Application No. 10-2024-0115555, filed in the Korean Intellectual Property Office on Aug. 28, 2024, which application is incorporated herein by reference in its entirety.

### BACKGROUND OF THE INVENTION

### 1. Field of the Invention

The present disclosure relates to a light-emitting and driving device package and a method for manufacturing the same, and more particularly, to a light-emitting and driving device package and its manufacturing method capable of improving optical efficiency while integrally packaging a light-emitting device and a driver IC.

### 2. Description of the Related Art

Conventionally, light-emitting and driving device packages have required complex wiring paths to electrically connect a substrate with a light-emitting device, or a substrate with a driver IC, or the light-emitting device with the driver IC. This complexity increases the manufacturing cost, degrades product quality, and introduces various process-related issues.

Furthermore, in conventional light-emitting and driving device packages, the driver IC is directly exposed along the optical path, causing a portion of the light emitted from the light-emitting device to be absorbed by the driver IC, thereby significantly reducing optical efficiency. In addition, heat generated from both the light-emitting device and the driver IC is not effectively dissipated, leading to serious degradation in durability and reliability.

### SUMMARY OF THE INVENTION

According to an aspect of the present disclosure, a light-emitting and driving device package includes a substrate having a first pad portion and a second pad portion. A driver IC is mounted on the first pad portion of the substrate, and a light-emitting device is mounted on the second pad portion to emit light in response to a drive signal from the driver IC. A first encapsulant is formed on the substrate in the shape of a wall, and a second encapsulant is provided to cover and protect at least a portion of the driver IC. A third encapsulant is further provided to cover and protect at least a portion of the light-emitting device.

According to another aspect of the present disclosure, a method of manufacturing a light-emitting and driving device package may include the steps of (a1) preparing a substrate on which a first pad portion and a second pad portion are formed, (b1) forming a first encapsulant in a wall shape on the substrate, (c1) mounting a driver IC on the first pad portion of the substrate and mounting a light-emitting device on the second pad portion so that it emits light in response to a drive signal from the driver IC, (d1) forming a second encapsulant that covers and protects at least a portion of the driver IC, and (e1) forming a third encapsulant that covers and protects at least a portion of the light-emitting device.

According to another aspect of the present disclosure, a method of manufacturing a light-emitting and driving device package may include the steps of (a2) preparing a substrate in which a first pad portion and a second pad portion are formed, (b2) mounting a driver IC on the first pad portion of the substrate, (c2) forming a first encapsulant in a wall shape on the substrate and forming a second encapsulant that covers and protects at least a portion of the driver IC, (d2) mounting a light-emitting device on the second pad portion so that it emits light in response to a drive signal from the driver IC, and (e2) forming a third encapsulant that covers and protects at least a portion of the light-emitting device.

### BRIEF DESCRIPTION OF THE DRAWINGS

The above and other features and advantages of the present disclosure will become more apparent by describing in detail embodiments thereof with reference to the attached drawings in which:

FIG. 1 is a perspective view illustrating a light-emitting and driving device package according to some embodiments of the present disclosure.

FIG. 2 is a cross-sectional view of the light-emitting and driving device package shown in FIG. 1.

FIG. 3 is a plan view of the light-emitting and driving device package shown in FIG. 1.

FIG. 4A to FIG. 4F are a set of cross-sectional views illustrating various embodiments of the second encapsulant of the light-emitting and driving device package shown in FIG. 1.

FIGS. 5 to 9 are cross-sectional views sequentially illustrating a manufacturing process of the light-emitting and driving device package shown in FIG. 1.

FIG. 10 is a cross-sectional view illustrating another light-emitting and driving device package according to other embodiments of the present disclosure.

FIGS. 11 to 15 are cross-sectional views sequentially illustrating a manufacturing process of the light-emitting and driving device package shown in FIG. 10.

FIG. 16 is a cross-sectional view illustrating still another light-emitting and driving device package according to further embodiments of the present disclosure.

FIGS. 17 to 21 are cross-sectional views sequentially illustrating a manufacturing process of the light-emitting and driving device package shown in FIG. 16.

FIG. 22(a) and FIG. 22(b) are a set of cross-sectional views illustrating various embodiments of the second encapsulant of the light-emitting and driving device package shown in FIG. 16.

FIG. 23 is a cross-sectional view illustrating yet another light-emitting and driving device package according to further embodiments of the present disclosure.

FIGS. 24 to 27 are cross-sectional views sequentially illustrating a manufacturing process of the light-emitting and driving device package shown in FIG. 23.

FIG. 28 is a flowchart illustrating a method of manufacturing a light-emitting and driving device package according to some embodiments of the present disclosure.

FIG. 29 is a flowchart illustrating a method of manufacturing a light-emitting and driving device package according to other embodiments of the present disclosure.

### DETAILED DESCRIPTION OF THE INVENTION

Hereinafter, preferred embodiments of the present disclosure will be described in detail with reference to the accompanying drawings.

The embodiments of the present disclosure are provided to fully convey the scope and spirit of the disclosure to those skilled in the art. These embodiments may be modified in various forms, and the scope of the disclosure is not limited to the specific embodiments described herein. Rather, these embodiments are provided to make this disclosure more thorough and complete and to fully convey the concept of the disclosure to those skilled in the art. In addition, the thicknesses and dimensions of the respective layers shown in the drawings are exaggerated for clarity and convenience of explanation.

Throughout the specification, when a layer, region, or substrate is referred to as being “on,” “connected to,” “stacked on,” or “coupled to” another element, it may mean that the element is directly on, connected to, stacked on, or coupled to the other element, or that other elements may be interposed therebetween. In contrast, when an element is referred to as being “directly on,” “directly connected to,” or “directly coupled to” another element, it is understood that there are no intervening elements between them. The same reference numerals refer to the same elements.

As used in the present specification, the terms “first,” “second,” are used to distinguish various components, parts, regions, layers, and/or portions, but such terms should not be construed as limiting. These terms are used only to distinguish one element from another. Thus, a “first” component, part, region, layer, or portion discussed below could equally be referred to as a “second” component, part, region, layer, or portion without departing from the teachings of the present disclosure.

The present disclosure aims to address the aforementioned problems by providing a light-emitting and driving device package and a method for manufacturing the same. In particular, the disclosure separates a region for accommodating a driver IC and a region for accommodating a light-emitting device on a substrate, encapsulates each region independently using different encapsulants, and employs a flip-chip type driver IC and light-emitting device to reduce manufacturing costs and process complexity, while significantly improving product quality, durability, and reliability. Additionally, it enhances optical efficiency. It should be understood, however, that these problems are presented by way of example only and do not limit the scope of the present disclosure.

According to one embodiment of the present disclosure, the regions of the substrate for accommodating the driver IC and the light-emitting device are separated, which prevents the light emitted from the light-emitting device from being absorbed by the driver IC, thereby significantly increasing optical efficiency. In addition, using a first, second, and third encapsulant with different melting points enables differential encapsulation of the driver IC and the light-emitting device, and by employing flip-chip type devices, heat dissipation is improved, manufacturing cost and process steps are reduced, and product quality, durability, and reliability are significantly enhanced. Of course, such effects do not limit the scope of the present disclosure.

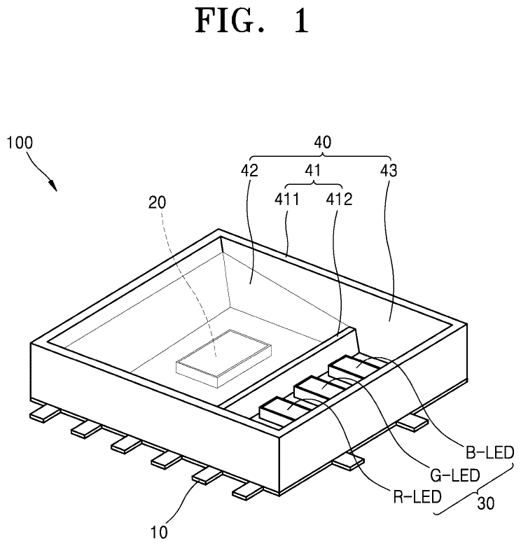

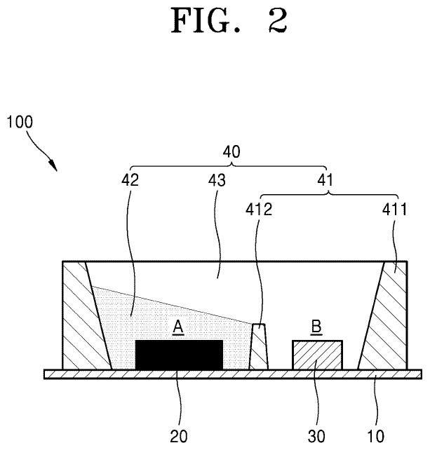

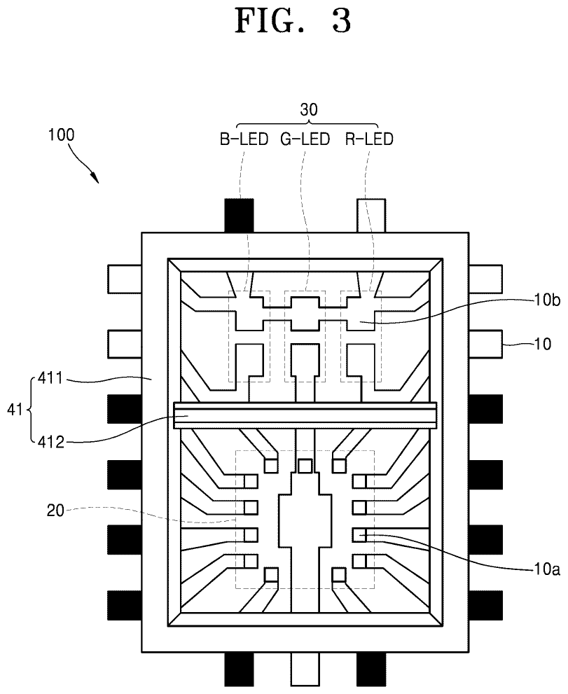

FIG. 1 is a perspective view illustrating a light-emitting and driving device package 100 according to some embodiments of the present disclosure. FIG. 2 is a cross-sectional view of the light-emitting and driving device package 100 shown in FIG. 1. FIG. 3 is a plan view of the light-emitting and driving device package 100 shown in FIG. 1.

Referring first to FIGS. 1 to 3, a light-emitting and driving device package 100 according to some embodiments of the present disclosure includes a substrate 10, a driver IC 20, a light-emitting device 30, and an encapsulant 40.

The substrate 10 includes a first pad portion 10a corresponding to the terminals of the driver IC 20 and a second pad portion 10b corresponding to the terminals of the light-emitting device 30. More specifically, the substrate 10 may be implemented as a lead frame formed by cutting a strip made of a conductive material.

However, the substrate 10 is not limited to this configuration, and various other types of substrates such as metal substrate, ceramic substrate, or printed circuit board may also be employed.

The driver IC 20 is mounted on the first pad portion 10a of the substrate 10. More specifically, the driver IC 20 may be implemented as a flip-chip type driver integrated circuit.

The driver IC 20 may be a driver IC with at least one channel configured to drive at least one light-emitting device 30, and may include at least one display driver integrated circuit (DDIC).

In other words, the driver IC 20 may be a driving component such as a one-channel or multi-channel driver IC that is electrically connected to the light-emitting device 30 through the substrate 10 and configured to drive the light-emitting device 30.

The driver IC 20 may include a drive chip having a drive circuit fabricated using a semiconductor process and a packaging member (molding material) that covers and protects the drive chip. The drive circuit may include various types of circuitry for supplying power to the light-emitting device 30, controlling the drive voltage, processing feedback signals, controlling the brightness of the light-emitting device 30, or compensating the luminous flux of the light-emitting device 30 based on a reference luminous flux of other light-emitting devices.

However, the driver IC 20 is not limited to the configuration shown in the drawings and may be formed in various three-dimensional shapes depending on the specifications, types, or configurations of the packages.

The light-emitting device 30 is mounted on the second pad portion 10b of the substrate 10 and may include at least one or a plurality of light-emitting devices that emit light in response to a drive signal from the driver IC 20. More specifically, the light-emitting device 30 may include flip-chip type red LED (R-LED), green LED (G-LED), and blue LED (B-LED).

The light-emitting device 30 may be, for example, a light output element disposed on one side of the substrate 10. More specifically, it may be implemented as an LED, micro LED, or mini LED capable of forming a pixel for display application.

For instance, the light-emitting device 30 may be a flip-chip type LED (Light Emitting Diode) having terminals formed on its lower surface.

The encapsulant 40 may be a type of packaging member (molding member) configured to cover and protect at least a portion of the substrate 10, the driver IC 20, and the light-emitting device 30.

More specifically, the encapsulant 40 may include a first encapsulant 41 formed on the substrate 10 in the shape of a wall, a second encapsulant 42 that covers and protects at least a portion of the driver IC 20, and a third encapsulant 43 that covers and protects at least a portion of the light-emitting device 30.

As shown in FIGS. 1 and 2, the first encapsulant 41 may include an outer wall portion 411 and an inner wall portion 412. The outer wall portion 411 may be formed in a rectangular ring shape along the edge of the substrate 10 and molded in a structure that is open at both the top and bottom. The inner wall portion 412 may be molded between the first pad portion 10a and the second pad portion 10b of the substrate 10 to partition a first cup portion A that accommodates the driver IC 20 and a second cup portion B that accommodates the light-emitting device 30.

More specifically, the first encapsulant 41 may be made of a first resin material having a first melting point, and may include one or more selected from epoxy molding compound (EMC), white epoxy molding compound (WEMC), polycyclohexylene terephthalate (PCT), polyphthalamide (PPA), and combinations thereof.

The first encapsulant 41 is not necessarily limited to the materials described above, and various other types and forms of resin materials may also be applicable.

As shown, for example, in FIG. 2, the second encapsulant 42 may be formed by molding or dispensing a light-blocking or light-reflective material that surrounds at least a portion of the driver IC 20. This is to prevent light emitted from the light-emitting device 30 from being absorbed by the driver IC 20.

More specifically, the second encapsulant 42 may be formed of a first or second resin material having a second melting point that is less than or equal to the first melting point. It may include one or more selected from white epoxy molding compound (WEMC), glass, quartz, ceramic, polymethyl methacrylate (PMMA), polycarbonate, silicone resin, and combinations thereof.

However, the second encapsulant 42 is not limited to these materials, and various other types and forms of resin materials may also be applicable.

The third encapsulant 43 may be a light-transmissive material that is molded or dispensed to surround at least a portion of the light-emitting device 30, allowing the light emitted from the light-emitting device to be discharged to the outside.

More specifically, the third encapsulant 43 may be formed of a third resin material having a third melting point that is less than or equal to the second melting point. It may include one or more selected from transparent EMC, clear molding compound epoxy (CMC), silicone, epoxy, silicon oxide, and combinations thereof.

In this configuration, the first melting point of the first encapsulant 41 is the highest among the three, so that the first encapsulant 41 does not melt when the second encapsulant 42 is molded or dispensed. The second melting point of the second encapsulant 42 is less than the first melting point, and the third melting point of the third encapsulant 43 is less than the second melting point, so that the second encapsulant 42 does not melt when the third encapsulant 43 is molded or dispensed.

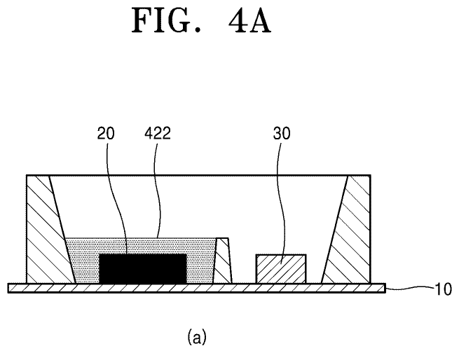

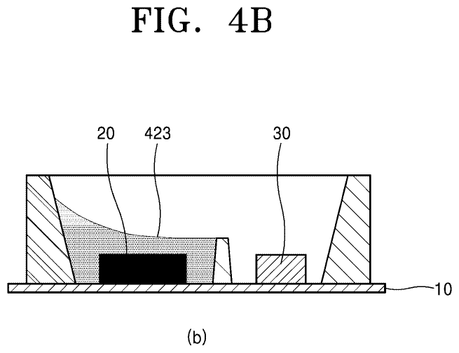

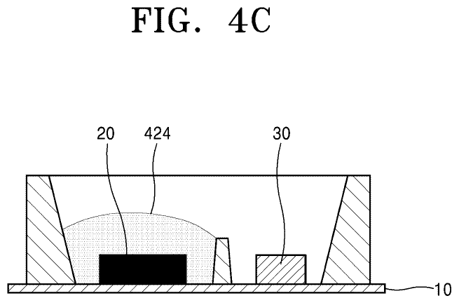

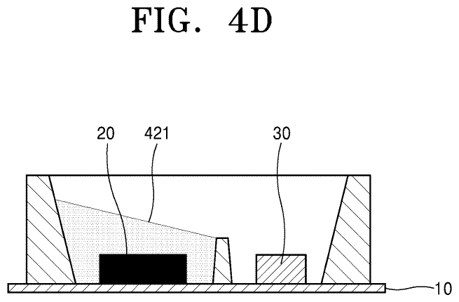

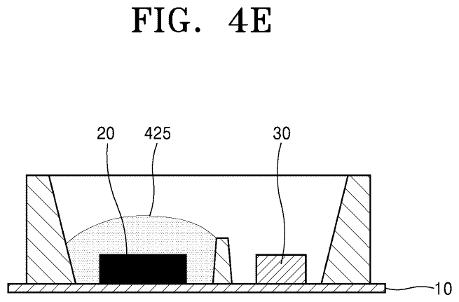

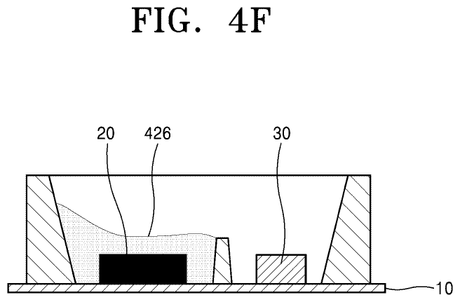

FIG. 4 is a set of cross-sectional views showing various embodiments of the second encapsulant 42 in the light-emitting and driving device package 100 of FIG. 1.

As illustrated in FIG. 4, the second encapsulant 42 of the light-emitting and driving device package 100, according to some embodiments of the present disclosure, may be formed in various shapes and may include a reflective surface that reflects light emitted from the light-emitting device 30 upward. For example, as shown in FIG. 4(d), it may include a reflective surface having an inclined surface 421 sloped toward the light-emitting device 30. Additionally, it may include other reflective surface shapes, such as a flat surface 422 as shown in FIG. 4(a), a concave surface 423 as shown in FIG. 4(b), an asymmetric convex surface 424 with one side higher than the other as shown in FIG. 4(c), a symmetric convex surface 425 with equal height on both sides as shown in FIG. 4(c), or a three-dimensional composite surface 426 having inclined, concave, and convex surfaces as shown in FIG. 4(f). All of these various forms may be applicable.

Accordingly, in the present disclosure, by separately partitioning the first cup portion (A) that accommodates the driver IC 20 and the second cup portion (B) that accommodates the light-emitting device 30 on the substrate 10, it is possible to prevent light generated from the light-emitting device 30 from being absorbed by the driver IC 20, thereby significantly increasing optical efficiency. Furthermore, by using the first encapsulant 41, the second encapsulant 42, and the third encapsulant 43, each having different melting points, the light-emitting device 30 and the driver IC 20 can be encapsulated selectively. Additionally, the use of flip-chip type driver ICs 20 and light-emitting devices 30 improves heat dissipation, thereby reducing product cost and manufacturing complexity while greatly enhancing quality, durability, and reliability.

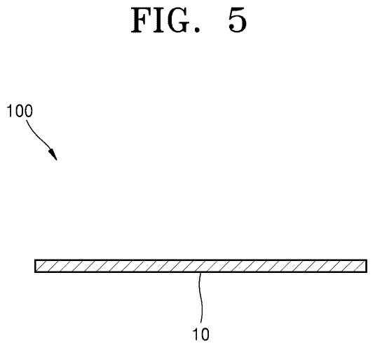

FIGS. 5 to 9 are cross-sectional views illustrating step-by-step the manufacturing process of the light-emitting and driving device package 100 shown in FIG. 1.

As shown in FIGS. 5 to 9, the manufacturing process of the light-emitting and driving device package 100 according to some embodiments of the present disclosure is as follows. First, as illustrated in FIG. 5, a substrate 10 is prepared in which a first pad portion 10a and a second pad portion 10b are formed.

At this time, the substrate 10 may be in the form of an uncut lead frame strip, but it is not limited thereto and may also include various other types of substrates.

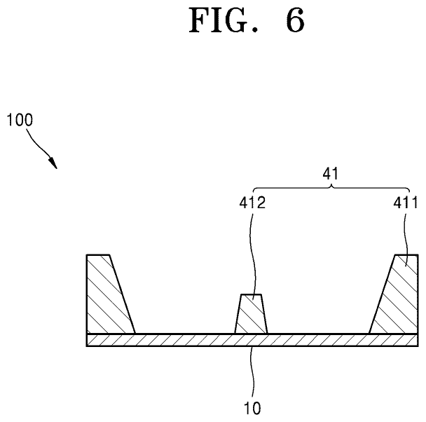

Next, as shown in FIG. 6, a first encapsulant 41 in the form of a wall is formed on the substrate 10.

Using a mold or the like, an outer wall portion 411 is molded along the edge of the substrate 10 in an open-top structure. At the same time, an inner wall portion 412 is molded between the first pad portion 10a and the second pad portion 10b to partition a first cup portion A for accommodating the driver IC 20 and a second cup portion B for accommodating the light-emitting device 30.

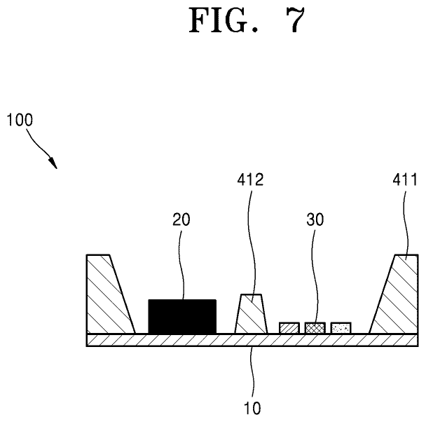

Next, as shown in FIG. 7, solder paste is printed onto the first pad portion 10a and the second pad portion 10b of the substrate 10. The driver IC 20 is mounted on the first pad portion 10a, and the light-emitting device 30, which emits light in response to a drive signal from the driver IC 20, is mounted on the second pad portion 10b.

At this time, the solder paste may be printed on the first and second pad portions using a three-dimensional printer. However, the method is not limited thereto, and the solder paste may be applied or dispensed using various other techniques.

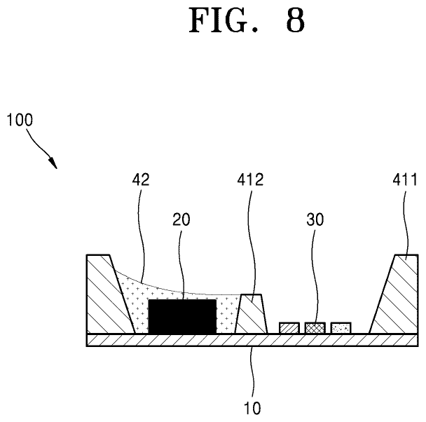

Subsequently, as shown in FIG. 8, a second encapsulant 42 is formed to cover and protect at least a portion of the driver IC 20.

In this step, the second encapsulant 42 may be primarily dispensed or molded in the first cup portion A that accommodates the driver IC 20.

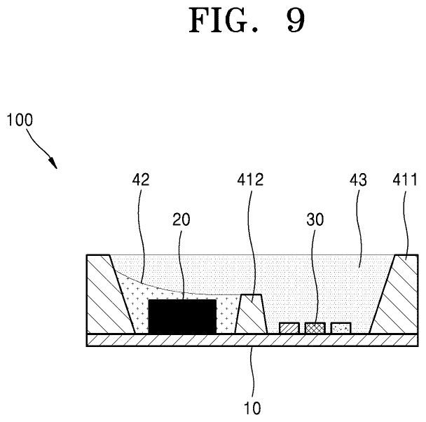

Next, as shown in FIG. 9, a third encapsulant 43 is formed to cover and protect at least a portion of the light-emitting device 30.

In this step, the third encapsulant 43 may be secondarily dispensed or molded in the second cup portion B that accommodates the light-emitting device 30.

Afterward, the substrate 10, which is in the form of a lead frame strip, may be singulated by cutting it into individual units.

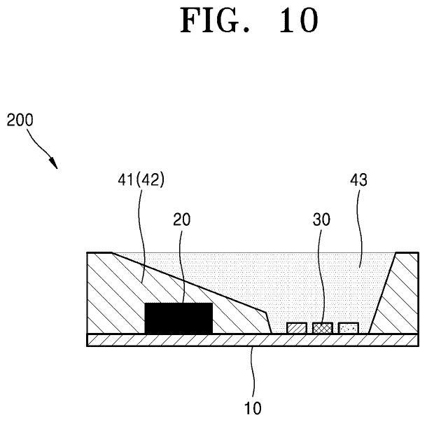

FIG. 10 is a cross-sectional view illustrating a light-emitting and driving device package 200 according to some other embodiments of the present disclosure.

As shown in FIG. 10, in the light-emitting and driving device package 200, the first encapsulant 41 and the second encapsulant 42 may be formed of the same material and may be integrally molded using white epoxy molding compound (WEMC).

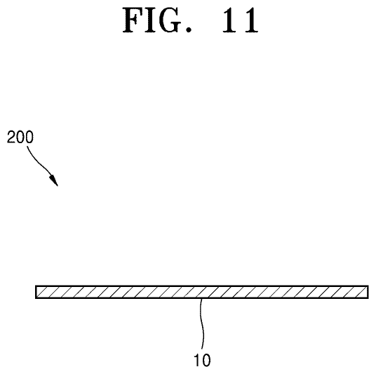

FIGS. 11 to 15 are cross-sectional views sequentially illustrating the manufacturing process of the light-emitting and driving device package 200 shown in FIG. 10.

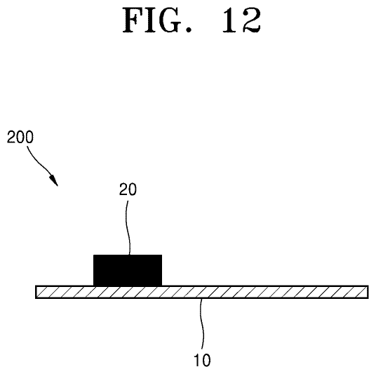

Referring to FIGS. 11 to 15, the manufacturing method according to some other embodiments is as follows. First, as shown in FIG. 11, a substrate 10 having a first pad portion 10a and a second pad portion 10b is prepared. Then, as illustrated in FIG. 12, solder paste is printed on the first pad portion 10a of the substrate 10, and the driver IC 20 is mounted thereon.

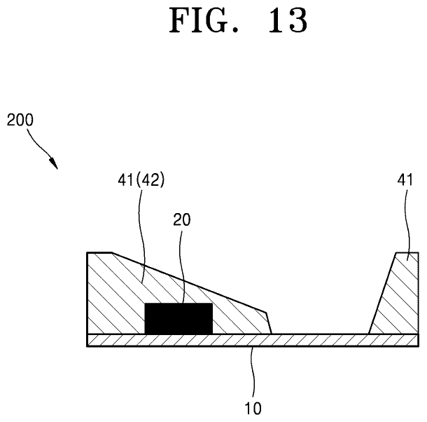

Subsequently, as shown in FIG. 13, a first encapsulant 41 in the form of a wall and a second encapsulant 42 that covers and protects at least a portion of the driver IC 20 are simultaneously molded on the substrate 10.

At this stage, the first encapsulant 41 and the second encapsulant 42 may be formed of the same material and may be integrally molded using white epoxy molding compound (WEMC).

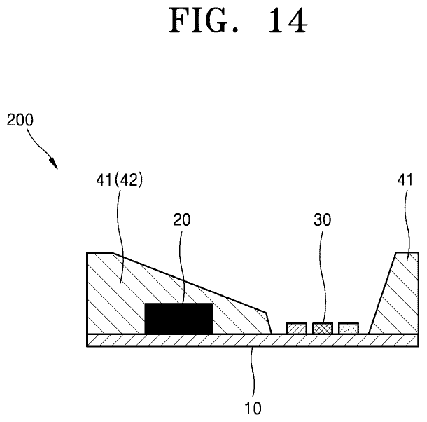

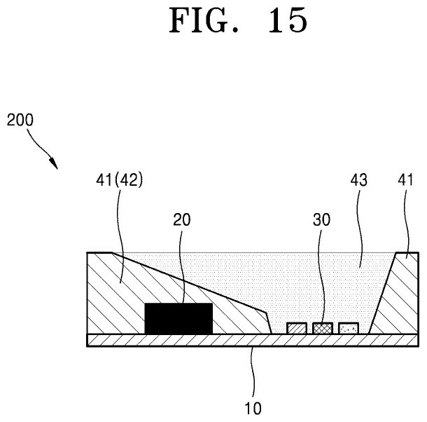

Next, as shown in FIG. 14, solder paste is printed on the second pad portion 10b of the substrate 10, and a light-emitting device 30 is mounted thereon, the device being configured to emit light in response to a drive signal from the driver IC 20. Subsequently, as illustrated in FIG. 15, a third encapsulant 43 is molded or dispensed to cover and protect at least a portion of the light-emitting device 30.

Accordingly, by using the first encapsulant 41 and the second encapsulant 42 formed of the same material, it is possible to prevent light emitted from the light-emitting device 30 from being absorbed by the driver IC 20, thereby significantly enhancing optical efficiency.

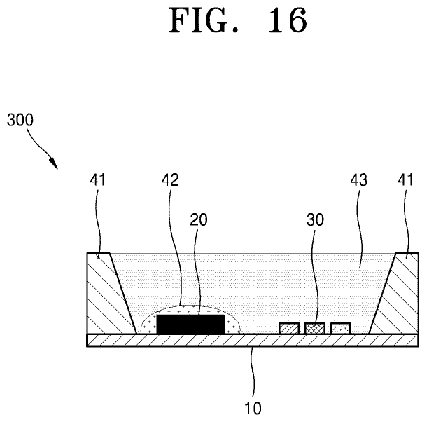

FIG. 16 is a cross-sectional view illustrating a light-emitting and driving device package 300 according to still some other embodiments of the present disclosure.

As shown in FIG. 16, in the light-emitting and driving device package 300, the inner wall portion 412 of the previously described first encapsulant 41 (see FIG. 2) may be omitted.

In this configuration, the second encapsulant 42 may be formed in a droplet-like shape, covering and protecting the driver IC 20.

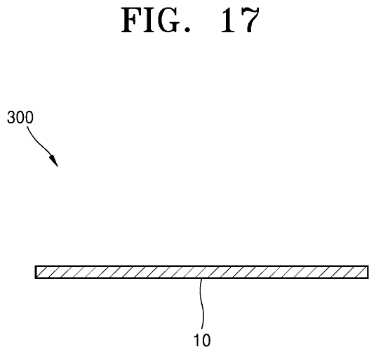

FIGS. 17 to 21 are cross-sectional views sequentially illustrating a manufacturing process of the light-emitting and driving device package 300 shown in FIG. 16.

Referring to FIGS. 17 to 21, the manufacturing process according to still some other embodiments of the present disclosure is described as follows. First, as illustrated in FIG. 17, a substrate 10 is prepared in which a first pad portion 10a and a second pad portion 10b are formed.

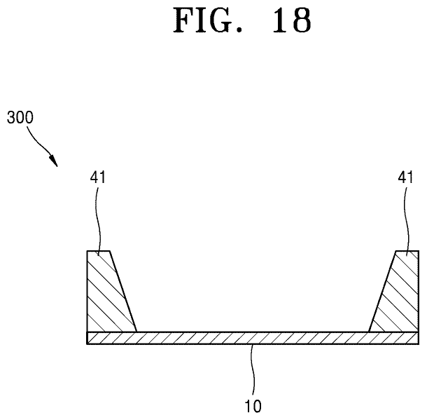

Next, as shown in FIG. 18, a first encapsulant 41 in the form of a wall is formed on the substrate 10.

At this stage, only the outer wall portion 411 may be molded in an open-top structure along the edge of the substrate 10 using a mold or other suitable means.

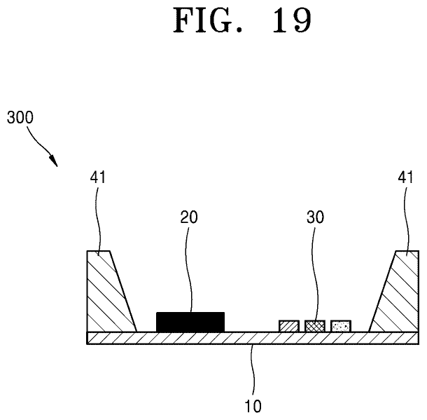

As shown in FIG. 19, solder paste is then printed on the first and second pad portions 10a and 10b, respectively. The driver IC 20 is mounted on the first pad portion 10a, and the light-emitting device 30, which emits light in response to a drive signal from the driver IC 20, is mounted on the second pad portion 10b.

The solder paste may be printed using a three-dimensional printer, although this is not limiting, and other techniques such as dispensing or screen printing may also be employed.

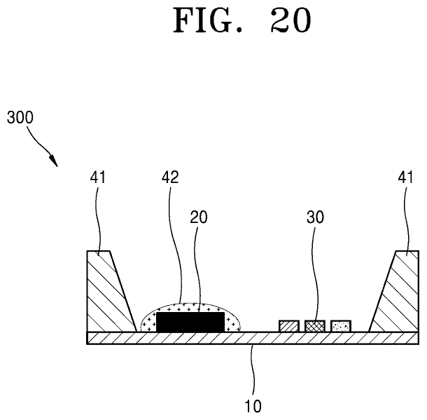

Subsequently, as illustrated in FIG. 20, a second encapsulant 42 is formed to cover and protect at least a portion of the driver IC 20.

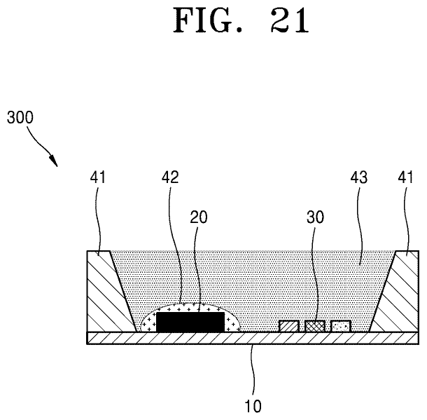

As shown in FIG. 21, a third encapsulant 43 is then formed to cover and protect at least a portion of the light-emitting device 30.

Accordingly, by employing the second encapsulant 42, it is possible to prevent light generated from the light-emitting device 30 from being absorbed by the driver IC 20, thereby significantly improving optical efficiency.

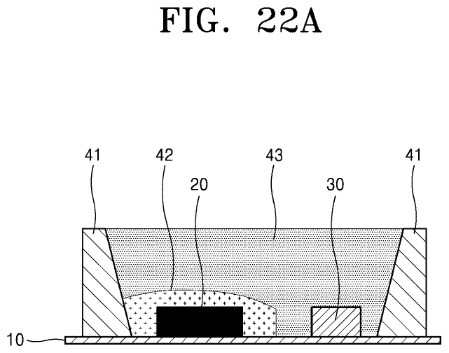

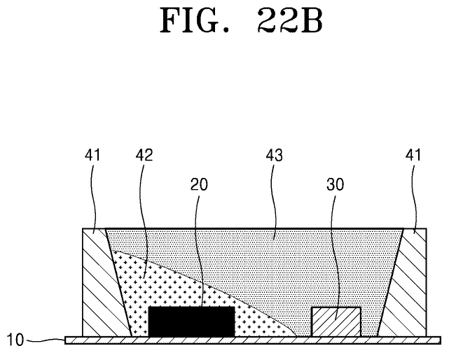

FIG. 22(a) and FIG. 22(b) show various embodiments of the second encapsulant 42 of the light-emitting and driving device package 300 shown in FIG. 16.

As illustrated in FIG. 22(a), the second encapsulant 42 may be formed in a lens-like shape to cover and protect the driver IC 20. Alternatively, as illustrated in FIG. 22(b), the second encapsulant 42 may be formed in an inclined surface shape to cover and protect the driver IC 20.

However, the shape of the second encapsulant 42 is not limited to the forms shown in the drawings, and it may be implemented in a wide variety of other shapes.

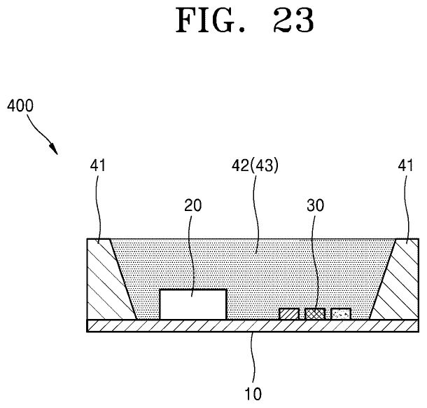

FIG. 23 is a cross-sectional view illustrating a light-emitting and driving device package 400 according to still some other embodiments of the present disclosure.

As shown in FIG. 23, in the light-emitting and driving device package 400, the driver IC 20 may be at least partially encapsulated with a molding material formed of white EMC, and both the second encapsulant 42 and the third encapsulant 43 may be formed of the same material and molded or dispensed integrally using transparent EMC or CMC (Clear Molding Compound Epoxy).

Accordingly, by employing a driver IC 20 that is packaged with a white EMC molding material, it is possible to prevent light emitted from the light-emitting device 30 from being absorbed by the driver IC 20, thereby significantly enhancing optical efficiency.

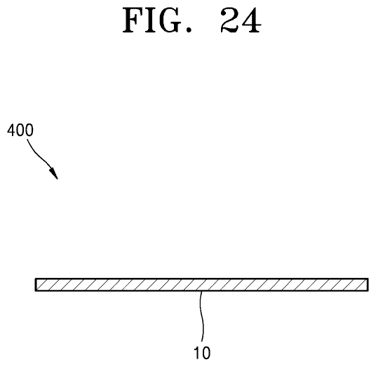

FIGS. 24 to 27 are cross-sectional views sequentially illustrating the manufacturing process of the light-emitting and driving device package 400 shown in FIG. 23.

Referring to FIGS. 24 to 27, the manufacturing process according to still some other embodiments of the present disclosure is described as follows. First, as illustrated in FIG. 24, a substrate 10 is prepared in which a first pad portion 10a and a second pad portion 10b are formed.

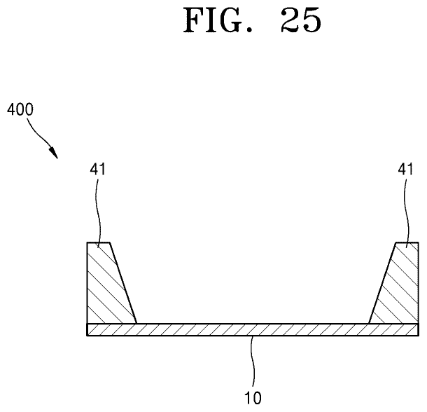

Next, as shown in FIG. 25, a first encapsulant 41 in the form of a wall is formed on the substrate 10.

At this stage, only the outer wall portion 411 may be molded in an open-top structure along the edge of the substrate 10 using a mold or other suitable means.

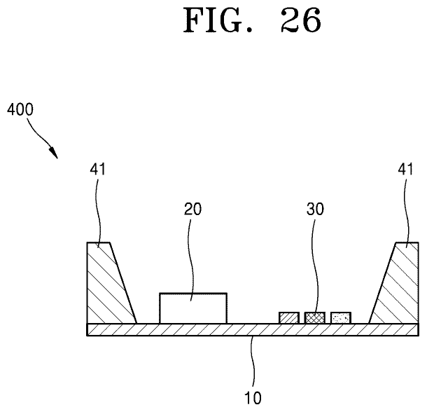

As illustrated in FIG. 26, solder paste is printed on the first pad portion 10a and the second pad portion 10b of the substrate 10. A driver IC 20, which has been pre-packaged using a molding material formed of white EMC, is mounted on the first pad portion 10a, and a light-emitting device 30, which emits light in response to a drive signal from the driver IC 20, is mounted on the second pad portion 10b.

The solder paste may be printed using a three-dimensional printer on both the first and second pad portions. However, the method is not limited thereto, and the solder paste may be applied or dispensed in a variety of other forms.

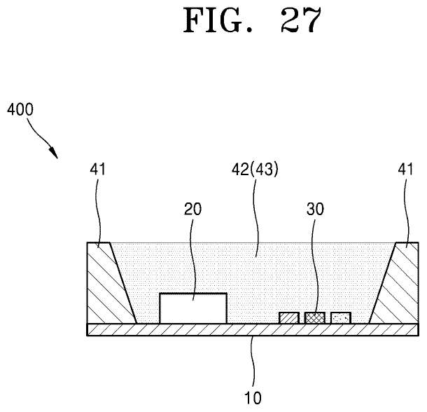

Next, as illustrated in FIG. 27, the second encapsulant 42, which covers and protects at least a portion of the driver IC 20, and the third encapsulant 43, which covers and protects at least a portion of the light-emitting device 30, may be simultaneously formed.

Accordingly, by utilizing a driver IC 20 packaged with a molding material formed of white EMC, it is possible to prevent light emitted from the light-emitting device 30 from being absorbed by the driver IC 20, thereby significantly improving optical efficiency.

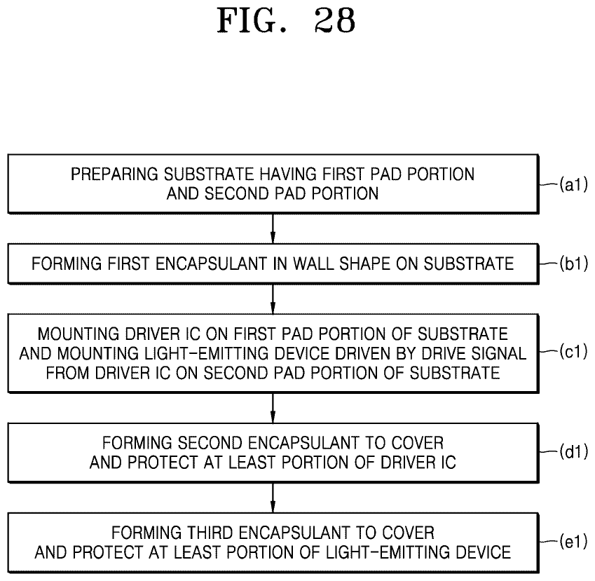

FIG. 28 is a flowchart illustrating a method of manufacturing the light-emitting and driving device packages 100, 300, and 400 according to some embodiments of the present disclosure.

As shown in FIGS. 1 to 28, the method of manufacturing the light-emitting and driving device packages 100, 300, and 400 includes the steps of (a1) preparing a substrate 10 having a first pad portion 10a and a second pad portion 10b, (b1) forming a first encapsulant 41 in the form of a wall on the substrate 10, (c1) printing solder paste on the first and second pad portions 10a and 10b, mounting a driver IC 20 on the first pad portion 10a, and mounting a light-emitting device 30 on the second pad portion 10b such that it emits light in response to a drive signal from the driver IC 20, (d1) forming a second encapsulant 42 to cover and protect at least a portion of the driver IC 20, and (e1) forming a third encapsulant 43 to cover and protect at least a portion of the light-emitting device 30.

In the step (b1), while the outer wall portion 411 is molded in an open-top structure along the edge of the substrate 10, an inner wall portion 412 may also be molded between the first pad portion 10a and the second pad portion 10b of the substrate 10. This forms a first cup portion A accommodating the driver IC 20 and a second cup portion B accommodating the light-emitting device 30.

In the step (d1), the second encapsulant 42 may be primarily dispensed or molded within the first cup portion A to cover and protect at least a portion of the driver IC 20.

In the step (e1), the third encapsulant 43 may be secondarily dispensed or molded within the second cup portion B to cover and protect at least a portion of the light-emitting device 30.

In the steps (d1) and (e1), the second encapsulant 42 and the third encapsulant 43 may be formed of the same light-transmissive material, and the material may be used to cover and protect at least a portion of both the driver IC 20 and the light-emitting device 30.

In the steps (d1) and (e1), the driver IC 20 may be at least partially formed of white EMC.

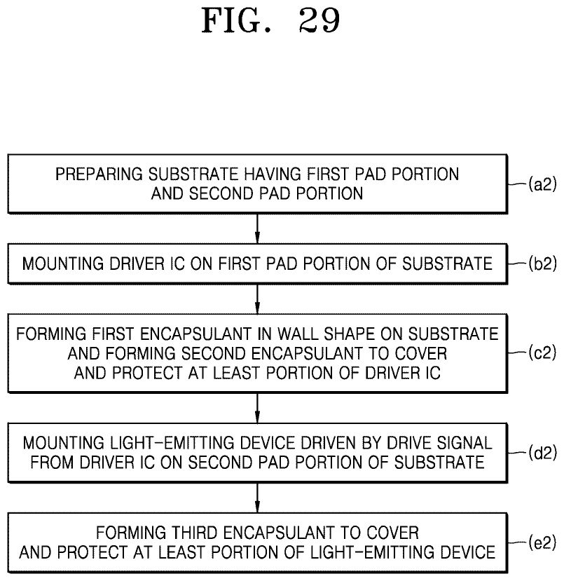

FIG. 29 is a flowchart illustrating a method of manufacturing the light-emitting and driving device package 200 according to some other embodiments of the present disclosure.

As shown in FIGS. 1 to 29, the method of manufacturing the light-emitting and driving device package 200 includes the steps of (a2) preparing a substrate 10 having a first pad portion 10a and a second pad portion 10b, (b2) printing solder paste on the first pad portion 10a of the substrate 10 and mounting the driver IC 20, (c2) forming a first encapsulant 41 in the form of a wall and a second encapsulant 42 that covers and protects at least a portion of the driver IC 20 on the substrate 10, (d2) printing solder paste on the second pad portion 10b and mounting a light-emitting device 30 that emits light in response to a drive signal from the driver IC 20, and (c2) forming a third encapsulant 43 to cover and protect at least a portion of the light-emitting device 30.

In the step (c2), the first encapsulant 41 and the second encapsulant 42 may be formed of the same material and may be integrally molded using white epoxy molding compound (WEMC).

While the present disclosure has been described with reference to the embodiments shown in the drawings, these embodiments are provided merely as examples. It will be understood by those skilled in the art that various modifications and equivalent alternative embodiments can be made based on the disclosed disclosure. Accordingly, the true scope of protection of the present disclosure should be defined by the technical spirit of the appended claims.

What is claimed is:

1. A light-emitting and driving device package comprising:
a substrate having a first pad portion and a second pad portion;
a driver IC mounted on the first pad portion of the substrate;
a light-emitting device mounted on the second pad portion of the substrate and configured to emit light in response to a drive signal from the driver IC;
a first encapsulant formed on the substrate and molded in the form of a wall;
a second encapsulant configured to cover and protect at least a portion of the driver IC; and
a third encapsulant configured to cover and protect at least a portion of the light-emitting device.

2. The light-emitting and driving device package of claim 1, wherein the substrate is a lead frame made of a conductive material.

3. The light-emitting and driving device package of claim 1, wherein the driver IC is a flip-chip type display driver integrated circuit (DDIC), and wherein the light-emitting device comprises flip-chip type red, green, and blue light-emitting diodes (LEDs).

4. The light-emitting and driving device package of claim 1, wherein the first encapsulant comprises an outer wall portion formed along an edge of the substrate and molded in an open-top structure.

5. The light-emitting and driving device package of claim 4, wherein the first encapsulant further comprises an inner wall portion molded between the first pad portion and the second pad portion of the substrate to define a first cup portion accommodating the driver IC and a second cup portion accommodating the light-emitting device.

6. The light-emitting and driving device package of claim 1, wherein the second encapsulant comprises a light-blocking or light-reflective material and is molded or dispensed to surround at least a portion of the driver IC so as to prevent light emitted from the light-emitting device from being absorbed by the driver IC.

7. The light-emitting and driving device package of claim 6, wherein the second encapsulant includes a reflective surface formed on at least a portion thereof, the reflective surface comprising at least one shape selected from the group consisting of an inclined surface sloped toward the light-emitting device, a flat surface, a concave surface, an asymmetric convex surface, a symmetric convex surface, and a composite surface comprising inclined, concave, and convex surfaces.

8. The light-emitting and driving device package of claim 1, wherein the third encapsulant is a light-transmissive material molded or dispensed in a manner surrounding at least a portion of the light-emitting device so that light generated from the light-emitting device is emitted to the outside.

9. The light-emitting and driving device package of claim 1, wherein the first encapsulant is made of a first resin material having a first melting point, the second encapsulant is made of the first resin material or a second resin material having a second melting point equal to or less than the first melting point, and the third encapsulant is made of a third resin material having a third melting point equal to or less than the second melting point.

10. The light-emitting and driving device package of claim 9, wherein the first encapsulant comprises at least one selected from the group consisting of epoxy molding compound (EMC), white epoxy molding compound (WEMC), polycyclohexylene terephthalate (PCT), polyphthalamide (PPA), and combinations thereof, wherein the second encapsulant comprises at least one selected from the group consisting of white epoxy molding compound (WEMC), glass, quartz, ceramic, polymethyl methacrylate (PMMA), polycarbonate, silicone resin, and combinations thereof, and wherein the third encapsulant comprises at least one selected from the group consisting of transparent EMC, clear molding compound epoxy (CMC), silicone, epoxy, silicon oxide, and combinations thereof.

11. The light-emitting and driving device package of claim 1, wherein the first encapsulant and the second encapsulant are made of the same material and are integrally molded using a white epoxy molding compound (WEMC).

12. The light-emitting and driving device package of claim 1, wherein at least a portion of the driver IC is made of white epoxy molding compound (WEMC), and wherein the second encapsulant and the third encapsulant are made of the same material and are integrally molded or dispensed using a transparent EMC or clear molding compound epoxy (CMC).

13. A method of manufacturing a light-emitting and driving device package, comprising:
(a1) preparing a substrate having a first pad portion and a second pad portion;
(b1) forming a first encapsulant in a wall shape on the substrate;
(c1) mounting a driver IC on the first pad portion of the substrate and mounting a light-emitting device on the second pad portion of the substrate, the light-emitting device being driven by a drive signal from the driver IC;
(d1) forming a second encapsulant to cover and protect at least a portion of the driver IC; and
(e1) forming a third encapsulant to cover and protect at least a portion of the light-emitting device.

14. The method of claim 13, wherein in the step (b1), an outer wall portion is molded on an edge of the substrate in an open-top structure, and simultaneously, an inner wall portion is molded between the first pad portion and the second pad portion of the substrate to define a first cup portion for accommodating the driver IC and a second cup portion for accommodating the light-emitting device.

15. The method of claim 14, wherein in the step (d1), the second encapsulant is primarily dispensed or molded into the first cup portion that accommodates the driver IC.

16. The method of claim 15, wherein in the step (e1), the third encapsulant is secondarily dispensed or molded into the second cup portion that accommodates the light-emitting device.

17. The method of claim 13, wherein in the steps (d1) and (e1), the second encapsulant and the third encapsulant are made of the same light-transmissive material, and the light-transmissive material is used to cover and protect at least a portion of the driver IC and at least a portion of the light-emitting device.

18. The method of claim 17, wherein in the steps (d1) and (e1), at least a portion of the driver IC is made of white epoxy molding compound (WEMC).

19. A method of manufacturing a light-emitting and driving device package, comprising:
(a2) preparing a substrate having a first pad portion and a second pad portion;
(b2) mounting a driver IC on the first pad portion of the substrate;
(c2) forming a first encapsulant in a wall shape on the substrate and forming a second encapsulant to cover and protect at least a portion of the driver IC;
(d2) mounting a light-emitting device on the second pad portion of the substrate, the light-emitting device being driven by a drive signal from the driver IC; and
(e2) forming a third encapsulant to cover and protect at least a portion of the light-emitting device.

20. The method of claim 19, wherein in the step (c2), wherein the first encapsulant and the second encapsulant are made of the same material and are integrally molded using a white epoxy molding compound (WEMC).
